(19) United States
(12) Patent Application Publication
(10) Pub. No.: US 2010/0140669 A1
(43) Pub. Date: Jun. 10, 2010

(54) MICROFABRICATION METHODS FOR FORMING ROBUST ISOLATION AND PACKAGING

(76) Inventor: Huikai Xie, Gainesville, FL (US)

Correspondence Address: MH2 TECHNOLOGY LAW GROUP, LLP, 1951 KIDWELL DRIVE, SUITE 550, TYSONS CORNER, VA, 22182, US

(21) Appl. No.: 12/514,357

(22) PCT Filed: Nov. 27, 2007
(86) PCT No.: PCT/US07/85609

§ 371 Date: May 11, 2009

Related U.S. Application Data
(60) Provisional application No. 60/867,278, filed on Nov. 27, 2006.

(51) Int. Cl. H01L 29/84; H01L 21/768; H01L 21/762

(52) U.S. Cl. 257/254; 438/700; 438/430; 438/51; 257/E29.324; 257/E21.545; 257/E21.577

(57) ABSTRACT

Exemplary embodiments provide an electrical single-crystal silicon (SCS) isolation device and a method for manufacturing the SCS isolation device. The isolation device can include a trench isolation structure formed using a trench having sidewall dielectrics and a follow-up filling of a metal or a polymer that is conductive or nonconductive. In an exemplary embodiment, metals such as a copper can be electroplated to fill the trench to provide robust mechanical support and a thermal conducting path for subsequent fabrication processes. In addition, exemplary embodiments provide a CMOS compatible process for self-packaging the disclosed isolation device or other devices from CMOS processing. In an exemplary embodiment, a backside packaging can be performed on a structured substrate prior to fabricating the active structures from the front side. Following the formation of the active structures (e.g., movable micro-sensors), a front-side packaging can be performed using bonding pads to complete the disclosed self-packaging process.

### RELATED APPLICATIONS

This application claims priority from U.S. Provisional Patent Application Ser. No. 60/867,278, filed Nov. 27, 2006, and PCT/US2007/085609, filed Nov. 27, 2007, which are hereby incorporated by reference in their entirety.

### FIELD OF THE INVENTION

This invention relates generally to microfabricated devices and, more particularly, to isolation and packaging techniques for microfabricated active devices.

### BACKGROUND OF THE INVENTION

Thin-film microstructures typically have poor robustness and high temperature dependence. In contrast, single-crystal silicon (SCS) has excellent mechanical properties for microfabricated active devices, such as micro-sensors, microactuators and resonators. However, electrical isolation and packaging of SCS microdevices are big challenges in the art

For example, a conventional solution to fulfill the SCS electrical isolation and packaging includes forming SCS islands on SOI (silicon on insulator) wafers and then wire-bonding directly on SCS islands, or re-filling trenches using polysilicon, or bonding another carrier wafer for providing electrical connections. However, these solutions have drawbacks and disadvantages, for example, due to limited applications, lack of design flexibility, and a high temperature requirement during the process.

Another conventional solution to fulfill the SCS electrical isolation and packaging includes using micro-loading effect of reactive-ion etch (RIE). For example, the micro-loading effect can be used for a cantilever beam structure that includes a stack of metal, oxide and silicon. During the RIE process, however, when the silicon under the proximal portion of the cantilever is completely undercut, the distal end of the cantilever can still have silicon remaining. Even though it may be small, the silicon undercut exists at the regions where undercut are undesired, resulting in lower sensitivity and signal-to-noise ratio. In addition, the electrical isolation region can only include thin-film layers since the silicon underneath is completely undercut, which therefore brings concerns on the large temperature variations and reduced mechanical robustness.

To overcome such undercut problems, a two-step etching has been used in the art to first etch silicon at the proximal portion with a complete undercut, and then to anisotropically etch silicon only at the remaining portion. However, this two-step etching also has drawbacks and disadvantages. For example, the second etching step can experience rising-temperature problems due to the thin proximal portion of cantilever beams. Also, the temperature drifts and poor overall robustness problems remain.

Thus, there is a need to overcome these and other problems of the prior art and to provide devices and techniques for manufacturing robust, self-packaged, integrated active devices for realizing electrical SCS isolation, overcoming thermal problems, eliminating thin-film structures, and achieving complete CMOS compatibility.

### SUMMARY OF THE INVENTION

According to various embodiments, the present teachings include a semiconductor device that includes trench isolation structures. The trench isolation structures can be interspersed through a semiconductor substrate structure to electrically isolate single-crystalline structures disposed thereover. The trench isolation structure can further include a filling material disposed in a trench that has a plurality of dielectric sidewalls.

According to various embodiments, the present teachings also include a method for fabricating a semiconductor device. In this method, trenches can be formed in a semiconductor substrate structure followed by a formation of dielectric sidewalls for each trench. A metal or a polymer can then be disposed in the trench that has dielectric sidewalls to form a trench isolation structure. Over the semiconductor substrate structure, active devices can then be formed and electrically isolated by the trench isolation structures.

According to various embodiments, the present teachings also include a method for forming a pattern in a deep trench. The pattern in a deep trench can be formed by first forming cavities in a semiconductor material and thereby leaving material line structures interspersed with the cavities on a semiconductor membrane. A thin-film layer can then be deposited on each surface of the material line structures and the bottoms of cavities, followed by removing the material line structures and thereby forming a trench. The trench can therefore have a trench bottom on the semiconductor membrane and the trench bottom can include a thin-film layer pattern due to the removal of the material line structures.

According to various embodiments, the present teachings further include a self-packaging method. In this method, an active device can be first formed to have a front side, and a backside including a structured substrate. The structured substrate can then be sealed by bonding a first wafer onto the backside of the active device. Active structures can then be formed on the front side of the active device followed by bonding a second wafer onto the formed active structures.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate several embodiments of the invention and together with the description, serve to explain the principles of the invention.

FIGS. 1A-1I depict cross-sectional views of an exemplary microdevice with SCS isolation at various stages of fabrication in accordance with the present teachings.

FIGS. 2A-2E depict cross-sectional views of an exemplary self-packaging process for an exemplary SCS-isolated microdevice at various stages of fabrication in accordance with the present teachings.

FIGS. 3A-3D depict cross-sectional views of an additional exemplary self-packaging process for the device shown in FIGS. 1A-1I at various stages of fabrication in accordance with the present teachings.

### DESCRIPTION OF THE EMBODIMENTS

Reference will now be made in detail to the present embodiments (exemplary embodiments) of the invention, examples of which are illustrated in the accompanying drawings. Wherever possible, the same reference numbers will be used throughout the drawings to refer to the same or like parts. In the following description, reference is made to the accompanying drawings that form a part thereof, and in which is shown by way of illustration specific exemplary embodiments in which the invention may be practiced. These embodiments are described in sufficient detail to enable those skilled in the art to practice the invention and it is to be understood that other embodiments may be utilized and that changes may be made without departing from the scope of the invention. The following description is, therefore, merely exemplary.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.” The term “at least one of” is used to mean one or more of the listed items can be selected.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less that 10” can assume negative values, e.g., −1, −2, −3, −10, −20, −30, etc.

Exemplary embodiments provide an electrical single-crystal silicon (SCS) isolation device and a method for manufacturing the SCS isolation device. The isolation device can include a trench isolation structure formed using a trench with sidewall dielectrics and a follow-up filling of a conductive material, such as a metal or a polymer. In an exemplary embodiment, the isolation device can be fabricated by first etching a trench in a CMOS silicon substrate and then forming trench sidewall dielectrics for isolation. Exemplary metals, such as copper, can then be electroplated to fill the trench to provide robust mechanical support and a thermal conducting path for subsequent fabrication processes. The isolated microstructures can be electrically interconnected through the metal layers from CMOS processing. For example, the isolated microstructure can be electrically contacts, such as, one or more of other active microstructures, CMOS circuitry, and bonding pads through the metal layers over the trench isolation structures.

In addition, exemplary embodiments provide a CMOS compatible process for self-packaging the disclosed isolation device or other devices from CMOS processing. In these processes, active microstructures (e.g., a micro-sensor) can be sealed from the backside (e.g., a structured substrate) of the active device prior to their fabrication process from the front side. The active device can then be packaged from the front side following their manufacture process having bonding pads for CMOS active area. In various embodiments, the active microstructures can include movable structures.

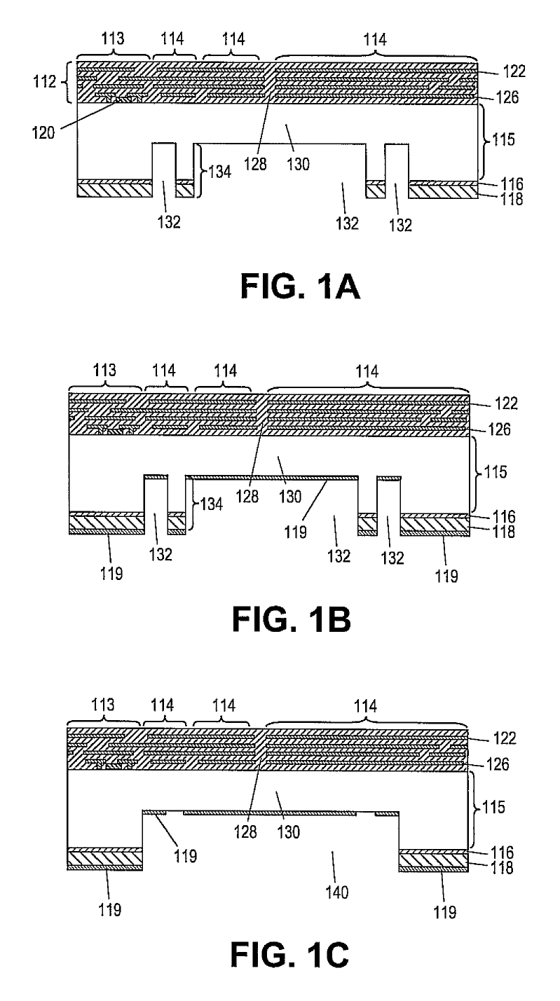

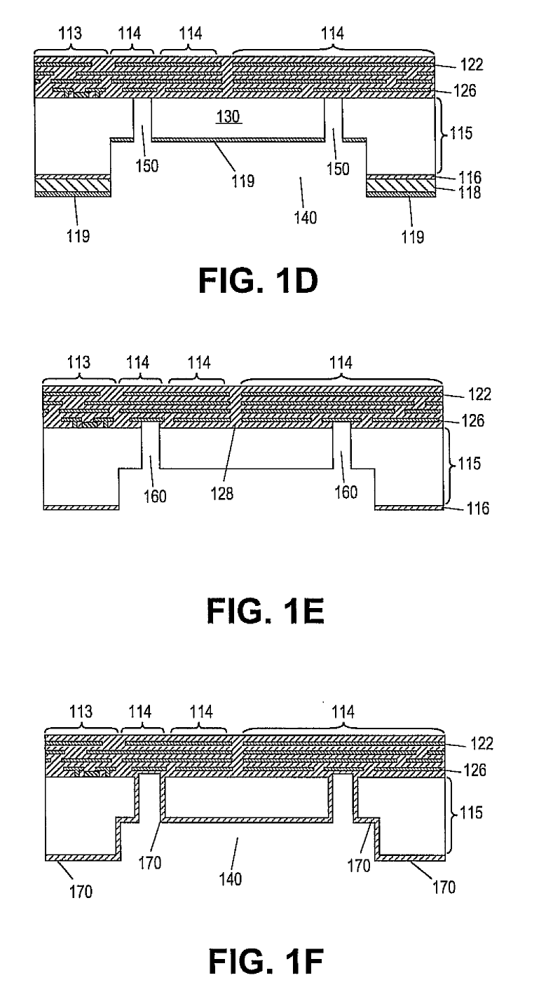

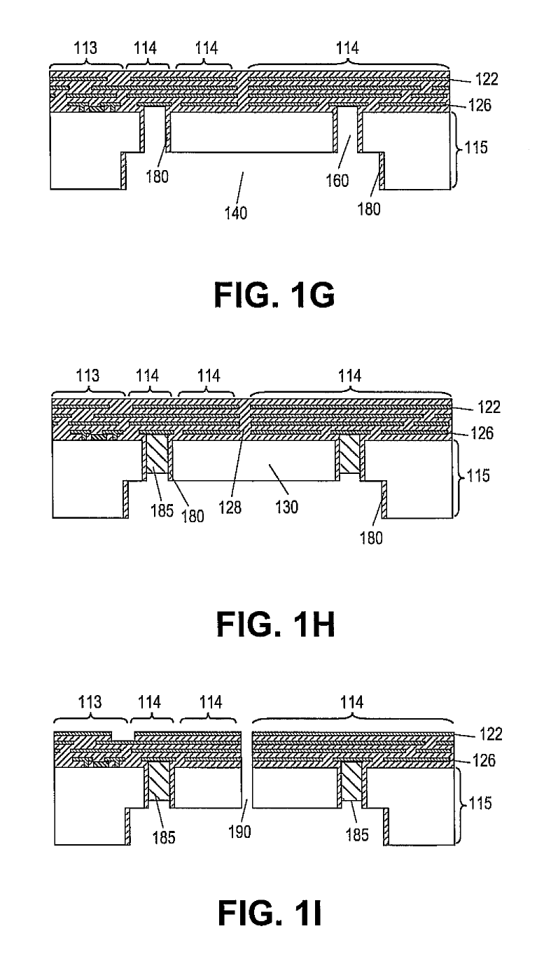

FIGS. 1A-1I depict cross-sectional views of an exemplary SCS isolation device 100 at various stages of fabrication in accordance with the present teachings. It should be readily apparent to one of ordinary skill in the art that the semiconductor device depicted in FIGS. 1A-1I represents a generalized schematic illustration and that other layers/structures can be added or existing layers/structures can be removed or modified.

In FIG. 1A, the device 100 can include active microstructures such as a composite thin film layer-stack 112 formed on a substrate 115, wherein the substrate 115 is located on backside of the device 100. The composite thin film layer-stack 112 can include a CMOS circuitry layer-stack, for example, a CMOS circuitry region 113 and microstructure regions 114 with CMOS interconnect metals formed according to standard CMOS processing techniques. The composite thin film 112 can also include dielectric layers 128. The dielectric layers 128 can include oxide materials such as silicon dioxide.

The CMOS circuitry layer-stack can include, for example, polysilicon layers 120 and metal layers, such as layer 122 or 126 shown in FIG. 1A. The metal layers can be formed of, for example, aluminum (Al) or copper (Cu). In various embodiments, portions of metal layers can be used as etch-resistant layers in the composite thin film 112.

The substrate 115 can be formed of a semiconductor material, for example, silicon such as single-crystal silicon (SCS), germanium, or a III-V group semiconductor. The thickness of the substrate 115 can be on the order of about 200 μm to about 750 μm with reference to a thickness of the composite thin film 112 that is on the order of about 1 μm to about 10 μm. For this reason, the substrate 115 can be sometimes referred to herein as a “bulk substrate,” or for the embodiment where the substrate 115 includes SCS, as a “bulk silicon.”

The substrate 115 can further include, for example, as shown in FIG. 1A, a substrate membrane 130, a plurality of openings 132, and one or more substrate line structures 134, formed by a backside etching of the substrate 115. Such backside etching can be performed using a layered structure as an etching mask. The layered mask structure can include a dielectric layer 116 and a photoresist layer 118 formed on the substrate 115 from the backside of the device 100. The dielectric layer 116 can be disposed between the substrate 115 and the photoresist layer 118. In various embodiments, the etching mask can include one layer, for example, the photoresist layer 118. By using the mentioned etching mask, a deep trench etch process, for example, DRIE (i.e., deep reactive ion etching), or advanced silicon etch process, can be used to etch the substrate 115 and thereby forming the substrate membrane 130, the openings 132 and the substrate line structures 134. For example, advanced silicon etch process can use alternating passivation and etch cycles to achieve the desired etching depth for the openings 132. The desired etching depth of the openings 132 can be characterized by the thickness of the substrate 115 with respect to the thickness of the substrate membrane 130. The desired thickness of the substrate membrane 130 can be, for example, about 1 μm or higher, such as ranging from about 10 μm to about 200 μm. In various embodiments, the backside etching can be performed by a two-side alignment.

In FIG. 1B, a thin-film layer 119, for example, a metal layer, can be deposited on the entire surface of the backside of the device 100 shown in FIG. 1A. The thin-film layer 119 can be formed by, for example, metal sputtering techniques known to one of ordinary skill in the art. As shown, the thin film layer 119 can cover the surface of the photoresist layer 118 and the bottom but not the sidewalls of each opening 132.

In FIG. 1C, the device 100 can include a backside trench 140 formed by merging the openings 132 by removing the substrate line structures 134. In an exemplary embodiment, when the substrate 115 is formed of silicon, the substrate line structures 134 can be removed by a silicon-undercut etching process, in which the thin-film layer 119 is used as an etching mask.

In FIG. 1D, the device 100 can include one or more cavities 150 formed in the substrate membrane 130 from the backside trench 140. The cavities 150 can be formed by a backside anisotropic etching of the device 100 by, for example, DRIE. In various embodiments, the backside etching process can be performed using the thin-film layer 119 as an etching mask.

In FIG. 1E, one or more trenches 160 can be formed by extending the cavities 150 into the composite thin film 112. For example, an etching process can be conducted at the bottom of the cavities 150 in FIG. 1D to remove a thin layer of the dielectric layers 128 of the composite thin film 112 using the thin-film layer 119 as an etching mask. The etching process can stop at the surface of a first-reached etch-resistant layer, for example, the metal layer 126. In various embodiments, this etching step can be optional and can be omitted. Then, the thin-film layer 119 and the photoresist layer 118 (see FIG. 1D) in the backside of the device 100 can be removed by known etching processes, for example, a dry plasma etch.

In FIG. 1F, a second dielectric layer 170 can be formed on both the surface and sidewalls of the backside structures of the device 100. For example, both the surfaces and the sidewalls of the backside trench 140 as well as the trenches 160 can be covered by the second dielectric layer 170. The dielectric layer 170 can be formed of any dielectric material known in the art, for example, silicon oxide formed by PECVD (plasma enhanced chemical vapor deposition).

In FIG. 1G, sidewall dielectric layers 180 can be formed by removing portions of the second dielectric layer 170, for example, by performing an anisotropic dielectric etch from the backside of the device 100. The removed portions can include those formed on the bottom surfaces of the backside trench 140 and the trenches 160. Accordingly, the sidewall dielectric layers 180 can be disposed on the sidewalls of both the trenches 160 and the backside trench 140.

In FIG. 1H, each of the trenches 160 with the sidewall dielectric layers 180 can be filled with a filling 185, conductive or nonconductive, such as a metal or a polymer. The filling 185 can be, for example, copper, which can provide, among other materials, mechanical stability and thermal performance. The filling 185 can be formed, in case of copper, by, for example, electroplating techniques, using the metal layer 126 at the bottom of the trenches 160 as a seed layer. In an exemplary embodiment, where the metal layer 126 is formed of aluminum, a zincate pretreatment can be performed before the formation of the metal filling 185.

In various embodiments, the filling 185 can include a polymer, conductive and/or nonconductive, including, but not limited to, polyimide, SU-8, polyacetylene, or polypyrrole. The polymer 185 can be filled in the trenches 160 and connected with the metal layer 126. The polymer 185 can be formed using a technique including, but not limited to, electroplating, spray coating, or spin coating.

Accordingly, the one or more trenches 160 including sidewall dielectric layers 180 and the filling 185 can provide SCS trench isolation, mechanical fortification, and thermal path for active micro-devices. Specifically, the sidewall dielectric layers 180 can provide electrical isolation for active microstructures, and the exemplary metal filling 185 can function as a good thermal conductor and a robust mechanical support. In various embodiments, the disclosed trench isolation structure can also be formed in a bulk substrate to provide an electrical isolation when active microstructures are formed thereon.

Subsequently, various active microstructures for electrical devices can be formed using the disclosed trench isolation structure. For example, a further step for forming active devices can be shown in FIG. 1I. As shown, a high-aspect-ratio trench 190 can be formed by etching through the composite thin film 112 and the substrate membrane 130 from the front side of the device 100. In various embodiments, the “etching through” process can include two steps of etching. First, an anisotropic etching can be used to etch portions of the dielectric layers 128 in the composite thin film 112. For example, a frontside etching process, such as, a reactive ion etch (RIE), can be used to expose the metal layer 122. The metal layer 122 can then be used as an etch mask to remove the portions of the dielectric layers 128 shown in FIG. 1H through the composite thin film 112. Second, a portion of the substrate membrane 130 can be removed by, for example, an anisotropic etching such as a DRIE using the metal layer 122 as the etching mask from the front side of the device 100. By utilizing a DRIE, sufficiently high aspect ratio structures with well-defined sidewalls can be achieved.

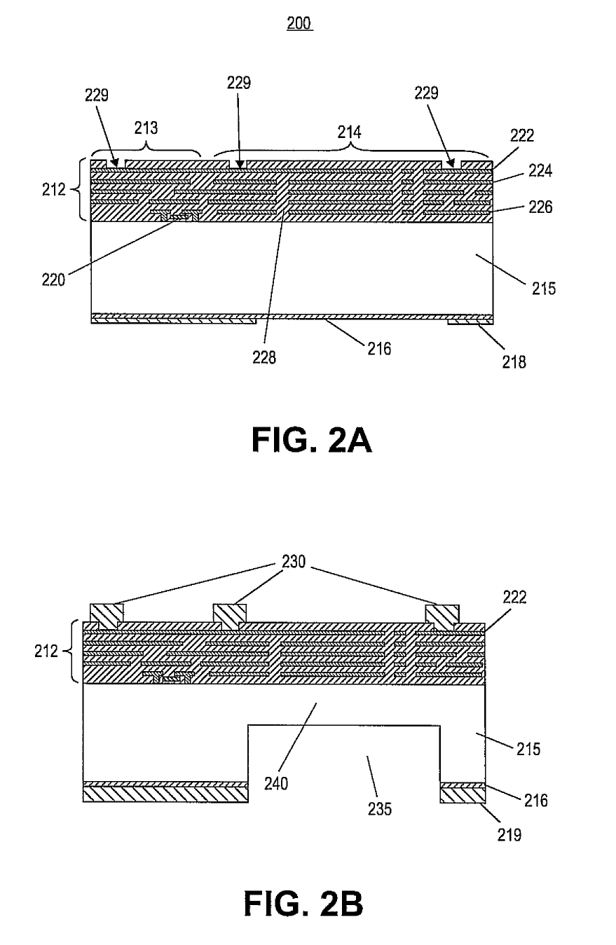

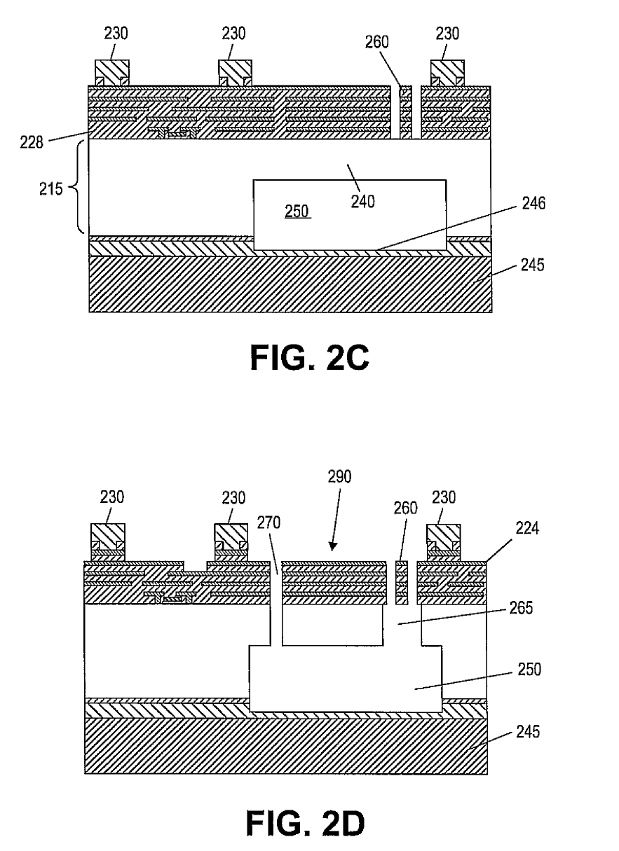

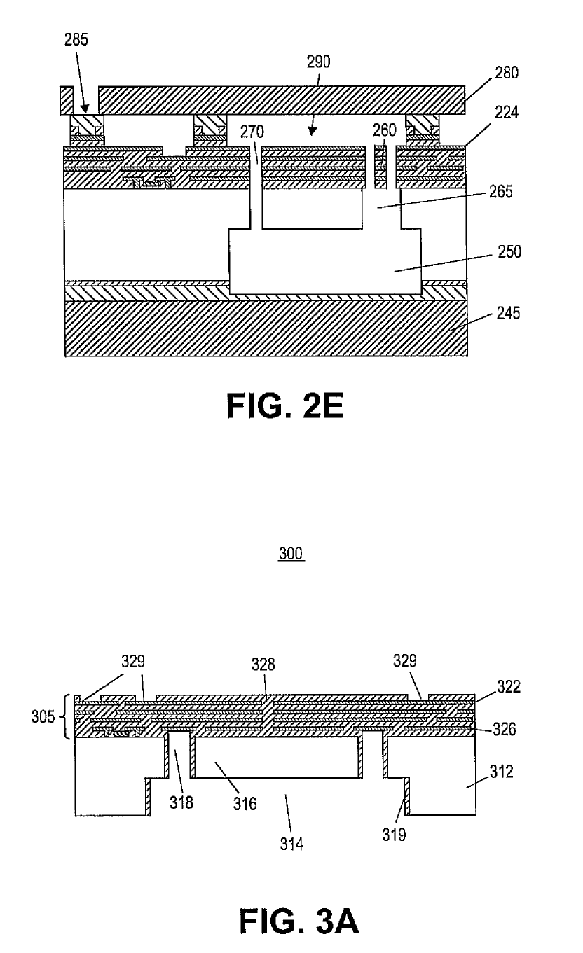

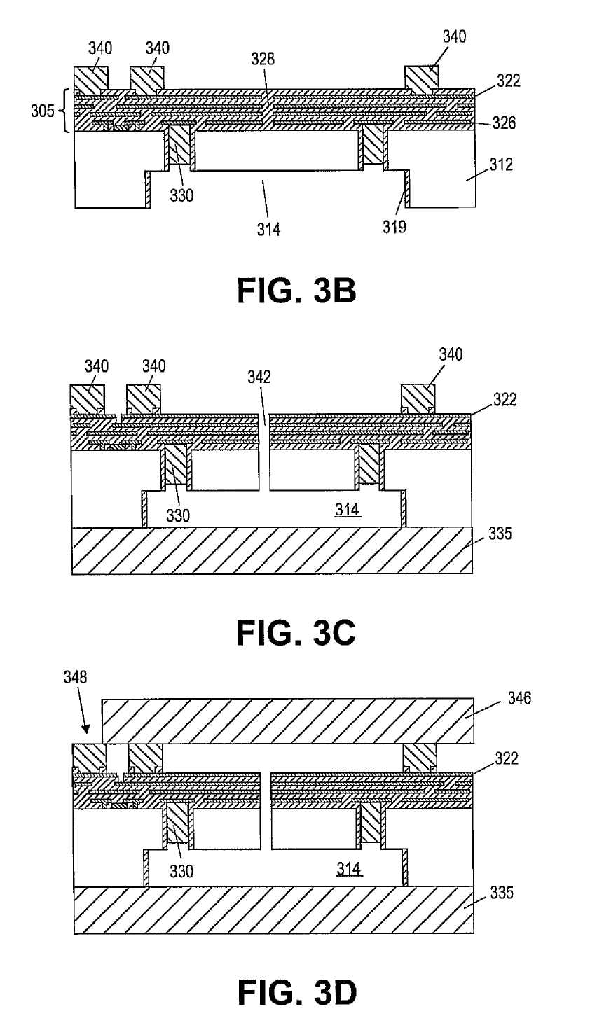

FIGS. 2A-2E and FIGS. 3A-3D further provide CMOS compatible microfabrication methods for self-packaging the disclosed isolation device or other devices from CMOS processing. In these processes, active microstructures (e.g., a micro-sensor) can be sealed (i.e., packaged) from the backside (e.g., where a structured substrate is present) of the active micro-device prior to their fabrication process from the front side. Following their manufacture process, the active micro-device can be packaged from the front side having bonding pads for the CMOS active area communication and/or for a protection of the formed microstructures. In various embodiments, the active microstructures can include movable structures.

FIGS. 2A-2E depict cross-sectional views of an exemplary self-packaging process for a microdevice 200 at various stages of fabrication in accordance with the present teachings. It should be readily apparent to one of ordinary skill in the art that the microdevice depicted in FIGS. 2A-2E represents a generalized schematic illustration and that other layers/structures can be added or existing layers/structures can be removed or modified.

FIG. 2A shows a composite thin film layer-stack 212 formed on a substrate 215 for the exemplary active microdevice 200. For example, the device 200 can be a CMOS MEMS (micro-electro-mechanical systems) sensor including CMOS electronics and MEMS active structures.

The composite thin film layer-stack 212 can include, for example, a CMOS circuitry layer-stack including a CMOS circuitry region 213 and CMOS interconnect regions 214 (e.g., for MEMS active structures) formed according to standard CMOS processing techniques. The CMOS circuitry layer-stack for the composite thin film 212 can include, for example, a polysilicon layer 220 and multiple metal layers, such as, for example, layer 222, 224 or 226. As shown, the metal layer 222 can include a plurality of exposed metal portions 229, which can be used as seed layers for subsequent formation of metal bumps. For example, the exposed metal portions 229 and the metal layer 222 can be formed, for example, of the same material of the bonding pads from standard CMOS processing. The metal layers can be formed of, for example, aluminum (Al) or copper (Cu). In various embodiments, portions of metal layers can be used as the etch-resistant layers. As shown, the CMOS circuitry layer-stack can further include dielectric layers 228 disposed around the polysilicon layer 220 and the multiple metal layers such as layer 222, 224 and 226.

The substrate 215 can include a semiconductor material, for example, silicon such as single-crystal silicon (SCS), or a III-V group semiconductor.

The microdevice 200 can also include a dielectric layer 216 and a patterned metal layer 218 on the backside of the substrate 215. In an exemplary embodiment, the dielectric layer 216 can be formed on the bottom surface of the substrate 215, for example, from a foundry CMOS process. The patterned metal layer 218 can then be formed on the dielectric layer 216 from backside of the device 200 as shown in FIG. 2A. The patterned metal layer 218 can be a seed layer for subsequent metal layer formation.

In FIG. 2B, a thick metal layer 219 and a plurality of metal bumps 230 can be formed respectively from the backside and the front side of the device 200. A cavity 235 can then be formed from the backside of the device 200.

Specifically, the thick metal layer 219 can be formed on the backside of the device 200 by, for example, electroplating metals on a seed layer such as the patterned metal layer 218. Accordingly, the thick metal layer 219 can be patterned based on the pattern of the patterned metal layer 218.

The plurality of metal bumps 230 can be formed on the front side of the device 200 using the metal portions 229 (see FIG. 2A) as a seed layer. The plurality of metal pads 230 can be used as bonding pads and/or sealing bumps for subsequent packaging process. In various embodiments, both the thick metal layer 219 and the plurality of metal bumps 230 can be formed of, for example, layered metal Ti/Cu/Au with an exemplary thickness of about 5 μm or higher. In an exemplary embodiment, the plurality of metal pads 230 can be formed on a CMOS bonding pad and formed of copper.

The cavity 235 can be formed by using the thick metal layer 219 as an etching mask to backside-etch the substrate 215 using, for example, DRIE, and thereby forming a substrate membrane 240 as a structured substrate.

In FIG. 2C, a first bonding wafer 245, for example, a glass wafer, a printed-circuit board, or a silicon wafer, can be bonded onto the structured substrate using, for example, thermo-compression techniques, from the backside of the device 200. As a result, the backside wafer bonding can form an enclosure 250. In various embodiments, the first bonding wafer 245 can be coated with a metal 246, such as gold. The metal 246 of the first bonding wafer 245 can be bonded with the thick metal layer 219. Alternatively, one or more of an alloy, a polymer, and an epoxy can be used as the bonding material as known in the art to bond the first bonding wafer 245 onto the backside of the device 200.

Still in FIG. 2C, a layer-stack microstructure 260 can be formed by a frontside anisotropic etching to remove portions of the dielectric layers 228 using the metal layer 222 as etching mask. The removal or etching process can be controlled to stop at the surface of the substrate 215.

In FIG. 2D, an isolation trench 265 can be formed by etching into the substrate membrane 240 using the metal layer 222 as the etching mask. The etching can be performed by, for example, a DRIE process plus silicon undercut etching. Thereafter, the metal layer 224 can be exposed by removing the overlaid metal layer 222 using, for example, a dry etch such as a Cl₂-based plasma etch.

Also in FIG. 2D, a high-aspect-ratio trench 270 can be formed by a two-step “etching through” process as described above. For example, the “etching through” process can include first etching through the dielectric stack 228 using the metal layer 224 as an etching mask, and then, etching through the substrate membrane 240 using a DRIE process. Consequently, a released microstructure 290 can be formed.

In FIG. 2E, a second bonding wafer 280 can be packaged on the front side of the device 200, specifically, on a surface of the plurality of metal bumps 230. The second bonding wafer 280 can be further patterned to expose one or more of the plurality of metal bumps 230 as a bonding pad (e.g., bonding pad 285) for, such as CMOS communications. The metal bumps 230 can also serve as a spacer to protect the formed microstructures, including the layer-stack microstructure 260 and the released microstructure 290.

FIGS. 3A-3D depict cross-sectional views of an additional exemplary self-packaging process for a microdevice 300 at various stages of fabrication in accordance with various embodiments. It should be readily apparent to one of ordinary skill in the art that the semiconductor microdevice depicted in FIGS. 3A-3D represents a generalized schematic illustration and that other layers/structures can be added or existing layers/structures can be removed or modified.

In FIG. 3A, the device 300 can include similar structures as shown in FIG. 1G including a CMOS circuitry layer-stack 305 on a substrate 312. The CMOS circuitry layer-stack 305 can include a plurality of metal layers, for example, layer 322 or 326, and dielectric layers 328. The metal layer 322 can include a plurality of exposed metal portions 329 as shown.

The substrate 312 can include a backside trench 314 and a substrate membrane 316. The substrate membrane 316 can include one or more trenches 318 formed through the substrate membrane 316 and connect the CMOS circuitry layer-stack 305 at the metal layer 326 as a bottom of the one or more trenches 318. In addition, the substrate 312 can also include sidewall dielectric layers 319 formed along all the sidewalls of the backside trench 314 and the trenches 318.

In FIG, 3B, the device 300 can include a plurality of metal bumps 340 formed on the front side. Specifically, the plurality of metal bumps 340 can be formed by, for example, electroplating, using the exposed metal portions 329 (see FIG. 3A) as seed layers. The plurality of metal pads 340 can be used as bonding pads and/or sealing bumps for subsequent packaging process. In various embodiments, the plurality of metal bumps 340 can be formed of, for example, layered metal Ti/Cu/Au.

Still in FIG. 3B, the device 300 can also include fillings 330 filled within the one or more trenches 318, wherein each trench 318 includes sidewall dielectric layers 319. As shown in FIG. 3B, each filling 330 in the trench 318 can connect active structures, for example, the CMOS circuitry layer-stack 305 at the metal layer 326. The fillings 330 can be, for example, copper, which can provide, among other things, mechanical stability and thermal performance. The metal filling 330 can be formed by, for example, electroplating techniques, using the metal layer 326 at the bottom of the trenches 318 as the seed layer. Accordingly, each trench 318 including sidewall dielectric layers 319 and the metal 330 can serve as a trench isolation structure for active devices.

In FIG. 3C, the device 300 can include a backside bonding wafer 335 to seal the backside trench 314 from the backside of the device. The backside bonding wafer 335 can be, for example, a glass wafer, a printed-circuit board, or a silicon wafer.

Following the backside packaging, as shown in FIG. 3C, a high-aspect-ratio trench 342 can be formed by etching through the CMOS circuitry layer-stack 305 and the substrate membrane 316 from the front side of the device 300. In various embodiments, the “etching through” process can include two steps of etching. For example, an anisotropic etching can be used to etch portions of the dielectric layers 328 of the CMOS circuitry layer-stack 305. Then, a portion of the substrate membrane 316 can be removed by a second anisotropic etching, such as DRIE, using the metal layer 322 as an etching mask from the front side. By utilizing a DRIE, sufficiently high aspect ratio structures with well-defined sidewalls can be achieved.

In FIG. 3D, a front-side bonding wafer 346 can be packaged on the front side of the device 300 to completely seal the formed microstructures shown in FIG. 3C. The front-side bonding wafer 346 can be packaged on the plurality of metal bumps 340. The front-side bonding wafer 346 can be further patterned to expose one of the plurality of metal bumps 340 as bonding pad 348 for CMOS communications.

In various embodiments, the disclosed trench isolation structure and its manufacturing method along with the self-packaging methods can be used for a variety of microdevices, for example, an accelerometer, a gyroscope, an actuator, a micromirror such as a ultra-flat fast-scanning micromirror, a micropositioner such as a high-accuracy large-displacement micropositioner, a resonator such as a high-Q resonator, and a MEMS switch such as a RF MEMS switch.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A semiconductor device comprising:
a semiconductor substrate structure;
one or more trench isolation structures interspersed through the semiconductor substrate structure, wherein each trench isolation structure comprises a filling material disposed in a trench that has a plurality of dielectric sidewalls; and
a plurality of single-crystalline structures disposed over and electrically isolated by the one or more trench isolation structures.

2. The device of claim 1, wherein the semiconductor substrate structure is a bulk semiconductor substrate or a semiconductor substrate membrane.

3. The device of claim 1, wherein the semiconductor substrate structure has a thickness of about 10 μm or higher.

4. The device of claim 1, wherein the semiconductor substrate structure comprises one or more materials selected from the group consisting of a silicon, a germanium, and a III-V group material.

5. The device of claim 1, wherein the filling material is a metal comprising a copper to provide mechanical support and thermal conductivity.

6. The device of claim 1, wherein the filling material comprises one or more polymers selected from the group consisting of polyimide, SU-8, polyacetylene, and polypyrrole.

7. The device of claim 1, wherein each single-crystalline structure electrically contacts one or more of a second active microstructure, CMOS circuitry and bonding pad through metal layers over the one or more trench isolation structures.

8. The device of claim 1, wherein the plurality of single-crystalline structures comprises CMOS interconnect layers and MEMS active structures.

9. The device of claim 1, wherein each of the plurality of single-crystalline structures comprises a device selected from the group consisting of an accelerometer, a gyroscope, a micromirror, an actuator, a micropositioner, a resonator, and a MEMS switch.

10. A method for fabricating a semiconductor device comprising:
forming one or more trenches in a semiconductor substrate structure;
forming a plurality of dielectric sidewalls for each of the one or more trenches;
filling one of a metal and a polymer in each trench that has the plurality of dielectric sidewalls to form a trench isolation structure; and
forming a plurality of active devices over the semiconductor substrate structure, wherein the plurality of active devices are electrically isolated by the trench isolation structure.

11. The method of claim 10, further comprising filling a copper in each trench using a technique comprising an electroplating process.

12. The method of claim 10, wherein filling each trench with a polymer comprises one or more processes of electroplating, spray coating, or spin coating.

13. A method for forming a pattern in a deep trench comprising:
forming a plurality of cavities in a semiconductor material and thereby leaving one or more material line structures interspersed with the plurality of cavities on a semiconductor membrane;
depositing a thin-film layer on a surface of each of the one or more material line structures and a bottom of each of the plurality of cavities; and
removing the one or more material line structures and thereby forming a trench that comprises a trench bottom on the semiconductor membrane, wherein the trench bottom comprises a thin-film layer pattern.

14. The method of claim 13, further comprising etching the semiconductor membrane from the trench bottom using the thin-film pattern as an etching mask.

15. The method of claim 13, wherein each of the plurality of cavities and the trench has a thickness of about 10 82 m to 100 μm less than a thickness of the semiconductor material.

16. A self-packaging method comprising:
forming an active device comprising a frontside and a backside, wherein the backside comprises a structured substrate;
bonding a first wafer onto the backside of the active device to seal the structured substrate;
forming one or more active structures on the front side of the active device; and
bonding a second wafer onto the one or more formed active structures.

17. The method of claim 16, wherein the structured substrate comprises a semiconductor substrate membrane having a thickness of about 10 μm to about 100 μm.

18. The method of claim 16, wherein bonding the first wafer onto the backside of the active device comprises a bonding material selected from the group consisting of a metal, an alloy, a polymer, and an epoxy.

19. The method of claim 16, wherein each of the first and the second wafer comprises a wafer selected from the group consisting of a glass wafer, a printed-circuit board, and a silicon wafer.

20. The method of claim 16, further comprising forming one or more movable active structures on the front side of the active device.

21. The method of claim 16, further comprising forming metal bumps onto the formed one or more active structures prior to the bonding of the second wafer to provide CMOS communications and to protect the formed active structures.

22. The method of claim 21, wherein each metal bump is formed on a CMOS bonding pad and formed of copper.

23. The method of claim 16, wherein the one or more active structures comprise one or more CMOS MEMS structures.

24. The method of claim 16, further comprising packaging an active device comprising one or more of an accelerometer, a gyroscope, a micromirror, a micropositioner, an actuator, a resonator, or a MEMS switch.
